(19) United States
(12) Patent Application Publication
(10) Pub. No.: US 2014/0356552 A1
(43) Pub. Date: Dec. 4, 2014

(54) HEATING EVAPORATION DEPOSITION APPARATUS AND EVAPORATION DEPOSITION METHOD USING THE SAME

(71) Applicant: Samsung Display Co., Ltd., Yongin-City (KR)

(72) Inventors: Daeyong KIM, Suwon-si (KR); Sukbeom YOU, Anyang-si (KR)

(73) Assignee: Samsung Display Co., Ltd., Yongin-City (KR)

(21) Appl. No.: 14/049,306

(22) Filed: Oct. 9, 2013

(30) Foreign Application Priority Data
May 30, 2013 (KR) 10-2013-0061824

(51) Int. Cl. C23C 16/50; H05B 3/02; H05B 3/03

(52) U.S. Cl. CPC C23C 16/50; H05B 3/03; H05B 3/023
USPC 427/593; 118/726

(57) ABSTRACT

A joule-heating evaporation deposition apparatus which deposits a layer on a target substrate, the apparatus including: a base substrate facing the target substrate including a plurality of target areas defined thereon; a plurality of heating electrodes on the base substrate; and a deposition material on the plurality of heating electrodes and an entire surface of the base substrate. Plural heating electrodes among the plurality of heating electrodes respectively face each target area among the plurality of target areas.

This application claims priority to Korean Patent Application No. 10-2013-0061824, filed on May 30, 2013, and all the benefits accruing therefrom under 35 U.S.C. §119, the contents of which are hereby incorporated by reference in its entirety.

### BACKGROUND

1. Field

The invention relates to a heating evaporation deposition apparatus and an evaporation deposition method using the same. More particularly, the invention relates to a heating evaporation deposition apparatus capable of forming a layer with uniform thickness and an evaporation deposition method using the heating evaporation deposition apparatus.

2. Description of the Related Art

As one thermal deposition method, a heating deposition method (otherwise referred to as a “joule-heating deposition method”) heats a deposition material to be evaporated and attaches the evaporated deposition material onto a substrate to form a layer. The joule-heating deposition method may be used in formation of an organic layer of an organic light emitting display device. The joule-heating deposition method is performed by disposing the deposition material on a base substrate provided with heating electrodes in a pattern, flowing an electrical current to the heating electrodes to heat the heating electrodes, and evaporating the deposition material in contact with the heating electrodes to deposit the deposition material on a target substrate in the pattern of the heating electrodes.

### SUMMARY

One or more exemplary embodiment of the invention provides a heating evaporation deposition apparatus capable of forming a layer with uniform thickness.

One or more exemplary embodiment of the invention provides an evaporation deposition method using the heating evaporation deposition apparatus.

An exemplary embodiment of the invention provides a heating evaporation deposition apparatus, which deposits a layer on a target substrate, including: a base substrate facing the target substrate including a plurality of target areas defined thereon; a plurality of heating electrodes on the base substrate; and a deposition material on the plurality of heating electrodes and an entire surface of the base substrate. Plural heating electrode among the plurality of heating electrodes respectively face each target area among the plurality of target areas.

The plural heating electrodes may include a pair of two heating electrodes among the plurality of heating electrodes.

A distance between adjacent heating electrodes among the plural heating electrodes may be about 20% to about 40% of an overall width of each of the target areas.

A width of each heating electrode among the plural heating electrodes respectively facing the each target area may be about 30% to about 40% of an overall width of the each target area.

A distance between adjacent heating electrodes among the plural heating electrodes may be about 20% to about 40% of the overall width of the each target area.

A distance between adjacent heating electrodes among the plural heating electrodes may be in a range from about 2 micrometers to about 4 micrometers.

A width of each heating electrode among the plural heating electrodes respectively facing the each target area may be in a range from about 3 micrometers to about 5 micrometers.

A distance between adjacent heating electrodes among the plural heating electrodes may be in a range from about 2 micrometers to about 4 micrometers.

A distance between the base substrate and the target substrate may be in a range from about 2 micrometers to about 4 micrometers.

The heating evaporation deposition apparatus may further include first and second common electrodes disposed at opposing sides of the base substrate, respectively, and the plurality of heating electrodes is between the first and second common electrodes and electrically connected to the first and second common electrodes.

The each target area among the plurality of target areas may have a rectangular planar shape elongated in a direction, and each heating electrode among the plural heating electrodes respectively facing the each target area may have an elongated bar shape corresponding to the rectangular planar shape of the each target area and extended in the direction.

The target substrate may be a display panel of a display device and a target area among the plurality of target areas may be a pixel area in which a pixel for the display panel is disposed.

The deposition material may include an organic light emitting material.

The heating evaporation deposition apparatus may further include a power supply connected to the plurality of heating electrodes to heat the plurality of heating electrodes, and the power supply may apply a pulse voltage to the plurality of heating electrodes to heat the plurality of heating electrodes.

The power supply may individually apply the pulse voltage to each of the plurality of heating electrodes.

An exemplary embodiment of the invention provides a heating evaporation deposition method, which deposits a layer on a target substrate, the method including providing a deposition material on an entire surface of a base substrate including a plurality of heating electrodes thereon; defining a plurality of target areas on the target substrate; disposing plural heating electrodes among the plurality of heating electrodes to face a corresponding target area among the plurality of target areas; and heating the plural heating electrodes such that the deposition material on each heating electrode among the plural heating electrodes, is deposited in the corresponding target area.

The plurality of heating electrodes may be substantially simultaneously heated.

The heating the plurality of heating electrodes includes applying a pulse voltage to the plurality of heating electrodes to heat the heating electrodes.

According to the above, plural heating electrodes among a plurality of heating electrodes on a substrate, are disposed to correspond to each target area among a plurality of target areas, and thus concentration of the deposition material evaporated by the plural heating electrodes in the center of the each target area, may be reduced or effectively prevented. As a result, the layer with uniform thickness may be providing in the each target area.

### BRIEF DESCRIPTION OF THE DRAWINGS

The above and other advantages of the invention will become readily apparent by reference to the following detailed description when considered in conjunction with the accompanying drawings wherein:

FIG. 1 is a cross-sectional view of an exemplary embodiment of a joule-heating evaporation deposition apparatus according to the invention;

FIG. 2 is a cross-sectional view of an exemplary embodiment of deposition of a deposition material by a first heating electrode according to the invention;

FIG. 3 is an enlarged cross-sectional view of an exemplary embodiment of a first heating electrode shown in FIG. 1;

FIG. 4 is a graph showing a deposition profile of a layer deposited by an exemplary embodiment of a joule-heating evaporation deposition apparatus according to the invention;

FIG. 5 is a plan view of an exemplary embodiment of a plurality of heating electrodes according to the invention;

FIG. 6 is a plan view of an exemplary embodiment of a target substrate on which a deposition material is deposited by the heating electrodes shown in FIG. 5;

FIG. 7a is a cross-sectional view of an exemplary embodiment of providing a deposition material in a joule-heating evaporation deposition method according to the invention;

FIG. 7b is a cross-sectional view of disposing a target substrate in the joule-heating evaporation deposition method according to the invention; and

FIG. 7c is a cross-sectional view of heating a heating electrode in the exemplary embodiment of the joule-heating evaporation deposition method according to the invention.

### DETAILED DESCRIPTION

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

In a heating deposition method (otherwise referred to as a “joule-heating deposition method”), when a deposition material is heated by heating electrodes and evaporated, the evaporated deposition material is diffused out in radial direction until the evaporated deposition material reaches a target substrate. Accordingly, a relatively large amount of the deposition material from a single heating electrode is deposited in a center portion of a target area of the target substrate in comparison to that deposited in a peripheral portion of the target area of the target substrate. Therefore, there remains a need for an improved deposition apparatus and method using the same, which deposits a uniform amount of deposition material on a target substrate.

Hereinafter, the invention will be explained in detail with reference to the accompanying drawings.

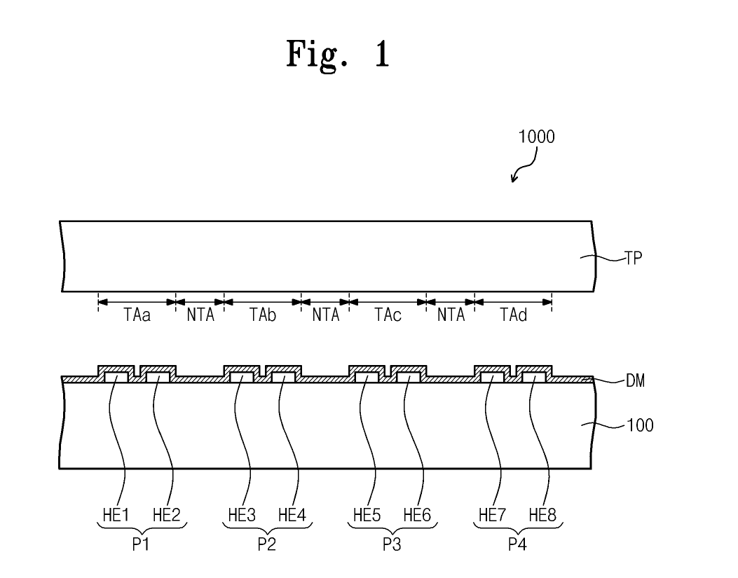

FIG. 1 is a cross-sectional view of an exemplary embodiment of a joule-heating 1000 evaporation deposition apparatus according to the invention.

Referring to FIG. 1, the joule-heating evaporation deposition apparatus 1000 includes a base substrate 100 and a plurality of heating electrodes HE1 to HE8. The heating electrodes HE1 to HE8 are arranged in a first direction (e.g., left-to-right in FIG. 1) to be spaced apart from each other at a predetermined distance.

A target substrate TP is disposed on the base substrate 100, and a deposition material DM is provided on the base substrate 100 and the heating electrodes HE1 to HE8. The deposition material DM may be disposed contacting the heating electrodes HE and between adjacent heating electrode HE, on the base substrate 100. For the convenience of explanation, FIG. 1 shows eight heating electrodes HE, but the number of the heating electrodes HE should not be limited to eight. The eight heating electrodes will be referred to as first to eighth heating electrodes HE1 to HE8, respectively.

The target substrate TP is disposed to face the base substrate 100 and includes a plurality of target areas defined thereon. Here, the target areas will be referred to as first, second, third and fourth target areas TAa to TAd. Each of the first to fourth target areas TAa to TAd is disposed to be spaced apart from an adjacent target area thereto, in the first direction.

The first to fourth target areas TAa to Tad are portions of the target substrate TP on which the deposition material is deposited, and a non-deposition area NTA is a portion of the target substrate on which the deposition material DM is not deposited. Portions of the non-deposition area NTA exist between the first to fourth target areas TAa to Tad, respectively. As an exemplary embodiment, the target area TA is alternately arranged with the non-target area NTA on the target substrate TP.

The target substrate TP may include, but is not limited to, a display device or a portion thereof. In an exemplary embodiment, the display device may include a display panel, and at least one of the first to fourth target areas TAa to TAd may be a pixel area of the display panel in which pixels are defined.

The deposition material DM is disposed on the base substrate 100 and the first to eighth heating electrodes HE1 to HE8 to cover the whole surface of the base substrate 100 and the first to eighth heating electrodes HE1 to HE8, but the area on which the deposition material DM is deposited should not be limited thereto or thereby. In one exemplary embodiment, for instance, the deposition material DM may be disposed only on and overlapping the first to eighth heating electrodes HE1 to HE8, such as upper and/or side surfaces of the first to eighth heating electrodes HE1 to HE8. In addition, according to another exemplary embodiment, the deposition material DM may be disposed only on a portion of the heating electrodes.

In an exemplary embodiment of providing the deposition material DM on the base substrate 100, the deposition material DM may be deposited by a thermal deposition method. Where the joule-heating evaporation deposition apparatus is used to manufacture an organic light emitting display device, the deposition material DM may be an organic material, e.g., Tris(8-hydroxyquinolinato)aluminum) (Alq3), used in formation of an organic layer of the organic light emitting display device.

The first to eighth heating electrodes HE1 to HE8 are disposed on the base substrate 100 to face a corresponding target area of the first to fourth target areas TAa to TAd. One or more heating electrodes HE are disposed to correspond to each target area.

In the illustrated exemplary embodiment, the first to eighth heating electrodes HE1 to HE8 are divided into four pairs or groups of heating electrodes, and each pair of the heating electrodes is arranged to correspond to one target area of the first to fourth target areas TAa to TAd. As shown in FIG. 1, a first electrode pair P1 including the first and second heating electrodes HE1 and HE2 is disposed to correspond to the first target area TAa and a second electrode pair P2 including the third and fourth heating electrodes HE3 and HE4 is disposed to correspond to the second target area TAb. Similarly, a third electrode pair P3 including the fifth and sixth heating electrodes HE5 and HE6 is disposed to correspond to the third target area TAc and a fourth electrode pair P4 including the seventh and eighth heating electrodes HE7 and HE8 is disposed to correspond to the fourth target area TAd. However, the number of the heating electrodes in each electrode group which is arranged to correspond to the corresponding target area should not be limited thereto or thereby.

The first to eighth heating electrodes HE1 to HE8 include a conductive material such as a metal material having an electrical conductivity, e.g., aluminum.

The first to eighth heating electrodes HE1 to HE8 are physically and/or electrically connected to a power supply (not shown). The power supply applies a voltage to the first to eighth heating electrodes HE1 to HE8 to flow an electrical current through the first to eighth heating electrodes HE1 to HE8, and thus the first to eighth heating electrodes HE1 to HE8 generate heat due to the electrical current. The heated first to eighth heating electrode HE1 to HE8 provide the heat to the deposition material DM disposed thereon. When the deposition material DM is heated to a temperature substantially equal to or higher than a temperature at which the deposition material DM is evaporated, the deposition material DM starts to evaporate. Thus, the deposition material DM disposed on the first and second heating electrodes HE1 and HE2 is transferred to the first target area TAa and the deposition material DM disposed on the third and fourth heating electrodes HE3 and HE4 is transferred to the second target area TAb. As described above, the deposition material DM on the first to eighth heating electrodes HE1 to HE8 is transferred to corresponding target areas TAa to TAd and a layer deposited by the joule-heating evaporation deposition apparatus is provided in the target areas TAa to Tad of the target substrate TP.

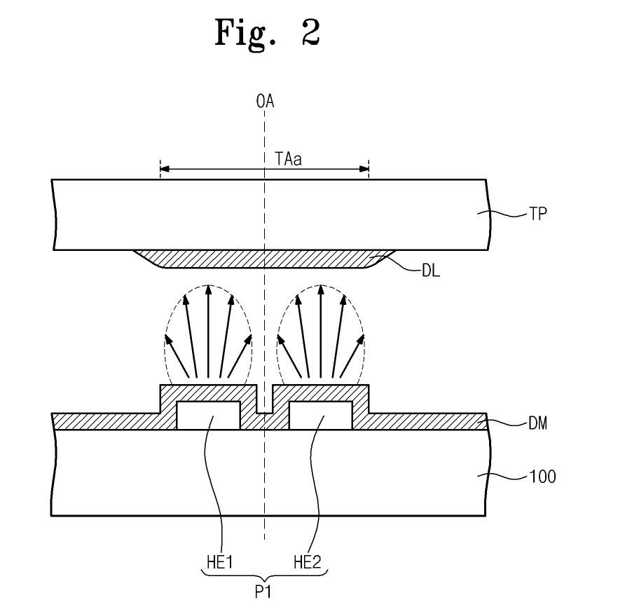

FIG. 2 is a cross-sectional view of an exemplary embodiment of deposition of a deposition material by a first heating electrode. FIG. 2 shows the layer deposited by the joule-heating evaporation deposition apparatus in the first target area TAa, but the layer is also deposited in the second, third, and fourth target areas TAb, TAc, and TAd in the same way as the first target area TAa. Therefore, the process of depositing the layer in the first target area TAa will be described in detail, and others will be omitted.

Referring to FIG. 2, due to the first and second heating electrodes HE1 and HE2 of the first electrode pair P1 disposed to correspond to the first target area TAa, the deposition material DM is deposited in the first target area TAs of the target substrate TP.

The first and second heating electrodes HE1 and HE2 are disposed to be spaced apart from each other while interposing therebetween an extension line OA, which crosses a center of the first target area TAa and is substantially vertical to the base substrate 100. The deposition material DM evaporated by the first and second heating electrodes HE1 and HE2 is diffused in a radial direction as illustrated by the groups of arrows and reaches the target substrate TP, thereby forming the layer DL. Accordingly, most of the deposition material DM (e.g., a first portion) evaporated from one heating electrode HE1 reaches an edge of the target area TAa located at the same position as the one heating electrode HE1 in a plan view. In contrast, only a second portion of the deposition material DM less than the first portion evaporated from one heating electrode HE1 reaches the center of the target area or an edge of the target area located at the same position as the other heating electrode HE2. Consequently, since a relatively small amount of the deposition material DM is respectively provided to the center of the target area TAa from both heating electrodes HE1 and HE2, a total amount of the deposition material DM provided to the center of the target area TAa corresponds to a total amount of the deposition material DM provided to the edge of the target area TAa and to a total amount of the deposition material DM provided between the center and the edge of the target area TAa, to thereby form the layer DL with uniform thickness.

In addition, since gas molecules evaporated from the heating electrodes HE1 and HE2 collide with each other while being diffused, the gas molecules are uniformly distributed to the whole surface of the target area TA, and thus the layer DL with uniform thickness is provided in the target areas TA.

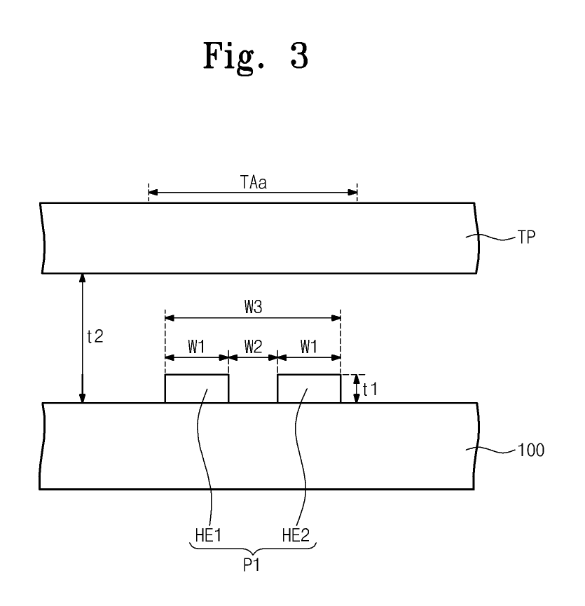

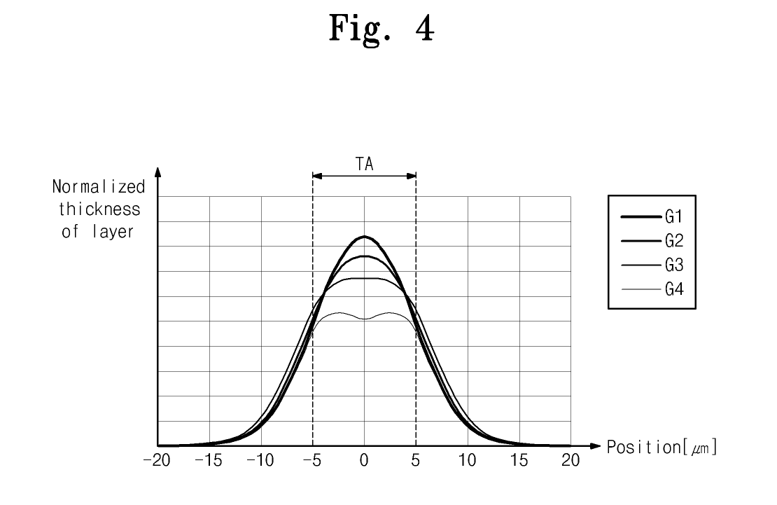

FIG. 3 is an enlarged cross-sectional view of an exemplary embodiment of a first heating electrode shown in FIG. 1, and FIG. 4 is a graph showing a deposition profile of a layer deposited by an exemplary embodiment of a joule-heating evaporation deposition apparatus according to the invention.

Referring to FIG. 3, when a width in the first direction of each of the first and second heating electrodes HE1 and HE2 is referred to as “W1” and a distance between the first and second heating electrodes HE1 and HE2 is referred to as “W2”, a width W3 of the first target area TAa is defined by about “2×W1+W2”.

Each of the first and second heating electrodes HE1 and HE2 has a cross-sectional thickness t1 of about 100 nanometers (nm) to about 500 nm, but is not limited thereto or thereby.

In the illustrated exemplary embodiment, a cross-sectional distance t2 between the base substrate 100 and the target substrate TP is in a range from about 2 micrometers (μm) to about 4 μm, but should not be limited thereto or thereby.

The distance W2 between the first and second heating electrodes HE1 and HE2 corresponds to about 20% to about 40% of the width W3 of the first target area TAa and the width W1 of the first and second heating electrodes HE1 and HE2 corresponds to about 30% to about 40% of the width W3 of the first target area TAa. In the illustrated exemplary embodiment, the distance W2 between the first and second heating electrodes HE1 and HE2 is in a range from about 2 μm to about 4 μm and the width W1 of each of the first and second heating electrodes HE1 and HE2 is in a range from about 3 to about 5 μm, but should not be limited thereto or thereby. That is, the distance W2 between the first and second heating electrodes HE1 and HE2 and the width W1 of each of the first and second heating electrodes HE1 and HE2 may be changed to uniformly deposit the deposition material DM in the target area TA.

Graph lines G2-G4 shown in FIG. 4 are obtained by providing a thickness of the layer deposited according to an exemplary embodiment of the invention, using a rarefied gas. The Comparative example represents a single heating electrode which defines zero (0) width W2 and is indicated by graph line G1. In FIG. 4, a horizontal axis indicates a relative position of the target area in μm with respect to the center of the heating electrode. A vertical axis indicates a normalized thickness of the layer at each relative position, which is obtained by dividing the thickness at each relative position by the largest thickness of the layer in a corresponding line of the graph lines. Referring to the Table below, in each embodiment, the width W1 of the heating electrodes is reduced by the increase of the distance W2 between the heating electrodes in order to uniformly maintain the overall width W3 of the target area.

TABLE

| | Comparative | Embodiment | Embodiment | Embodiment |
|---|---|---|---|---|
| | example | example 1 | example 2 | example 3 |
| Distance W2 | 0 | 3 μm | 4 μm | 5 μm |
| Width W1 | 10 μm | 3.5 μm/3.5 μm | 3 μm/3 μm | 2.5 μm/2.5 μm |

In the Comparative example representing a single heating electrode which defines zero (0) width W2 and indicated by graph line G1, the thickness of the layer is largest at the center of the target area TA (Position 0) and rapidly thins in a direction away from the center of the target area TA. However, in the Embodiment examples 1-3 representing a distance W2 between adjacent heating electrodes and indicated by graph lines G2-G4, when the distance W2 between the heating electrodes becomes relatively wide and the width W1 of the heating electrodes becomes relatively narrow, the thickness of the center of the target area TA is reduced, so that an overall thickness of the layer in the target area TA becomes uniform. In detail, when comparing the Embodiment example 1 indicated by graph line G2 to the Comparative example indicated by graph line G1, the Embodiment example 1 has a relatively even deposition profile at the center of the target area TA as compared to that of the Comparative example, and the thickness of the layer is uniform in the whole of the target area TA.

When comparing the Embodiment example 3 to the Embodiment example 2, the Embodiment example 3 indicated by graph line G4 has a deposition profile in which the deposition material DM is deposited at a smaller thickness than that of the Embodiment example 2 indicated by graph line G3, on the target substrate TP. The Embodiment example 3 indicated by graph line G4 has the deposition profile with two individual peaks, which is different from the Embodiment examples 1 and 2 with one peak. This is because in Embodiment example 3 having the largest distance W2 between adjacent heating electrodes, the collision between the gas molecules of the deposition material DM evaporated from the two heating electrodes is reduced and the gas molecules of the deposition material DM evaporated from the two heating electrodes are deposited substantially individually without being combined with or contacting each another.

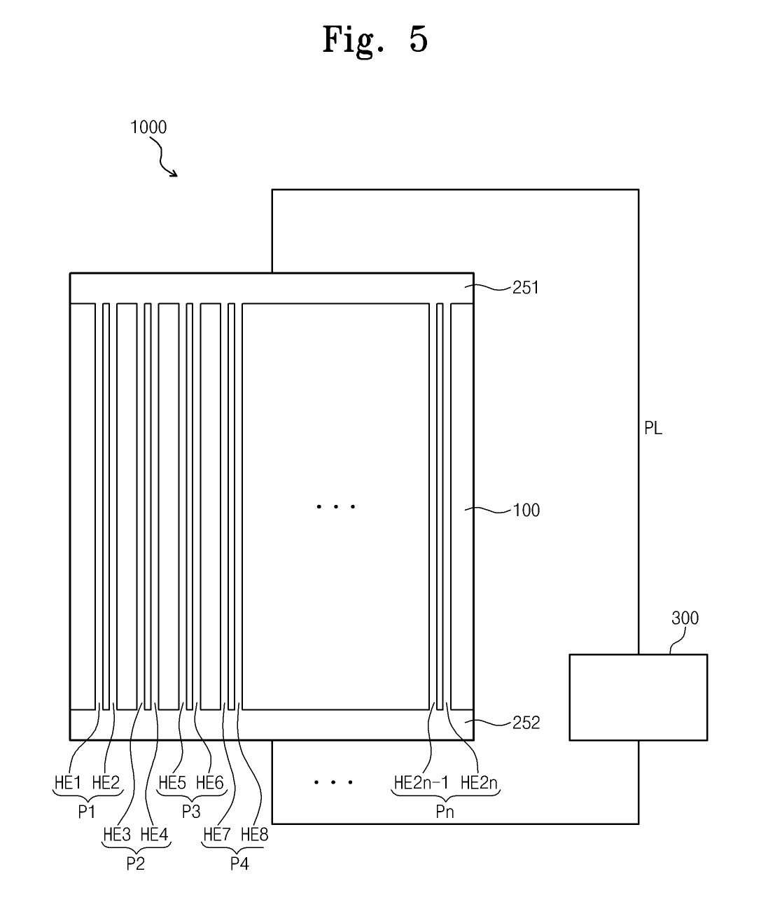

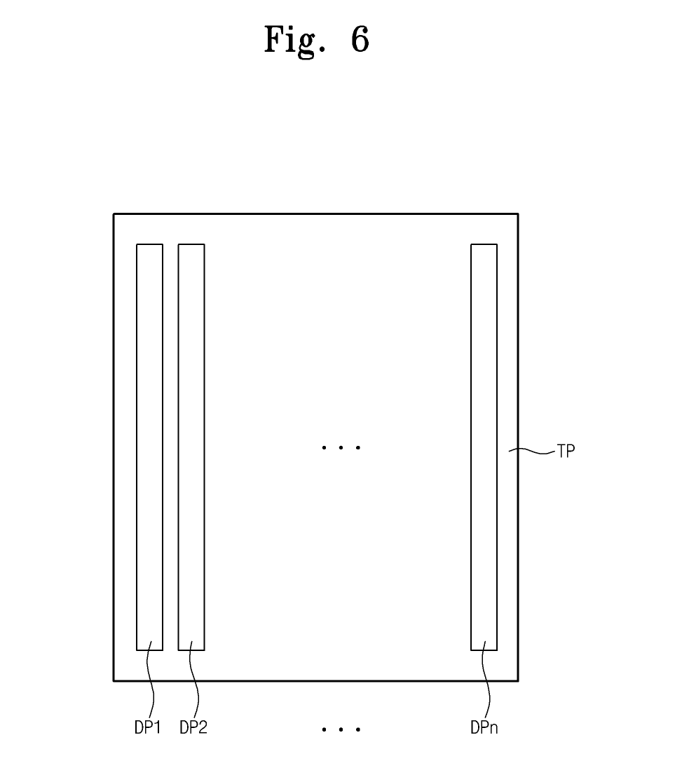

FIG. 5 is a plan view showing an exemplary embodiment of a plurality of heating electrodes according to the invention and FIG. 6 is a plan view showing an exemplary embodiment of a target substrate on which a deposition material is deposited by the heating electrodes shown in FIG. 5.

Referring to FIG. 5, a joule-heating evaporation deposition apparatus 1000 includes a base substrate 100, a plurality of heating electrodes HE1 to HE2n, a first common electrode 251, a second common electrode 252 and a power supply 300. The heating electrodes HE1 to HE2n, the first common electrode 251 and the second common electrode 252 may be a single, unitary, indivisible member, but the invention is not limited thereto or thereby. The base substrate 100 and the heating electrodes HE1 to HE2n have the similar configurations and functions as those of the base substrate 100 and the first to eighth heating electrodes HE1 to HE8, and thus detailed descriptions of the base substrate 100 and the heating electrodes HE1 and HE2n will be omitted.

The heating electrodes HE1 to HE2n have a shape and arrangement corresponding to a pattern shape of a plurality of target areas (not shown). When the target areas have a rectangular shape elongated to extend in one direction, each heating electrode HE1 to HE2n has the shape corresponding to the shape of the corresponding target area of the target areas, and has an elongated and uniform width bar shape extended in the one direction.

The first and second common electrodes 251 and 252 are disposed at opposing sides of the base substrate 100. The heating electrodes HE1 to HE2n are disposed between the first and second common electrodes 251 and 252 in the plan view. First ends of the heating electrodes HE1 to HE2n are electrically connected to the first common electrode 251 and opposing second ends of the heating electrodes HE1 to HE2n are electrically connected to the second common electrode 252. When a voltage is applied to the first and second common electrodes 251 and 252, the heating electrodes HE1 and HE2n are applied with a source voltage having the constant level since the heating electrodes HE1 to HE2n are commonly connected to the first and second common electrodes 251 and 252. Thus, a constant electrical current flows through the heating electrodes HE1 to HE2n, so that the deposition material DM adjacent to and on each heating electrode HE1 to HE2n is deposited at a constant speed.

The power supply 300 applies a pulse voltage to the heating electrodes HE1 to HE2n to instantly heat the heating electrodes HE1 to HE2n. The power supply 300 heats the heating electrodes HE1 to HE2n to a predetermined temperature sufficient to evaporate the deposition material DM. In one exemplary embodiment, for example, when the deposition material DM is Tris(8-hydroxyquinolinato)aluminum) (Alq3), the power supply 300 heats the heating electrodes HE1 to HE2n to about 600 degrees Kelvin (K).

The power supply 300 substantially simultaneously heats the heating electrodes HE1 to HE2n through the first and second common electrodes 251 and 252, but should not be limited thereto or thereby. In an alternative exemplary embodiment, a power supply 300 may be individually connected to each heating electrode HE1 to HE2n to individually apply the voltage to the heating electrodes HE1 to HE2n. With a plurality of individual power supplies 300, the power supplies 300 may respectively apply different currents to the heating electrodes HE1 to HE2n to allow the layer formed in the target area to have a uniform thickness.

Referring to FIGS. 5 and 6, the deposition material DM is deposited in the target area of the target substrate TP by the joule-heating evaporation deposition apparatus 1000. When the heating electrodes HE1 to HE2n are heated by the power supply 300, only the deposition material DM adjacent to the heating electrodes HE1 to HE2n is evaporated and deposited on the target substrate TP. Thus, the layer on the target substrate TP formed of the deposition material DM has the shape corresponding to that of the heating electrodes HE1 to HE2n. In detail, the deposition material DM on, adjacent to and/or between the first electrode pair P1 forms a first layer pattern DP1, the deposition material DM on, adjacent to and/or between the second electrode pair P2 forms a second layer pattern DP2, and the deposition material DM on, adjacent to and/or between an n-th electrode pair Pn forms an n-th layer pattern DPn. While the electrodes HE in a group may be spaced apart from each other on the base substrate 100, the layer on the target substrate TP formed of the deposition material DM on, adjacent to and/or between the electrodes in the group may be a single, unitary, indivisible layer member, owing to the deposition process described above with reference t FIG. 2.

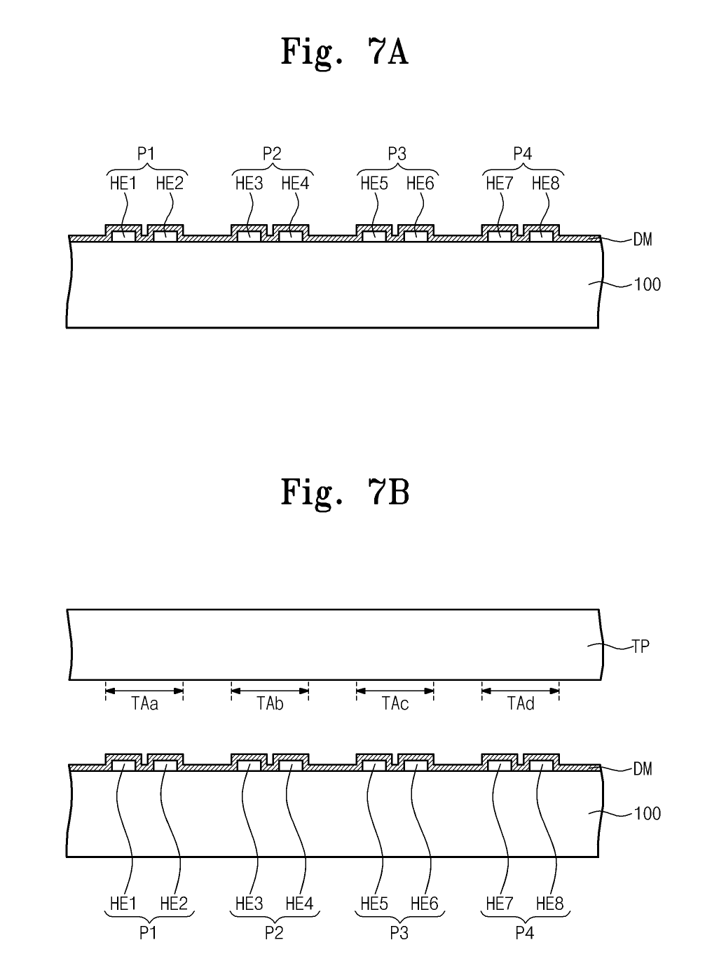

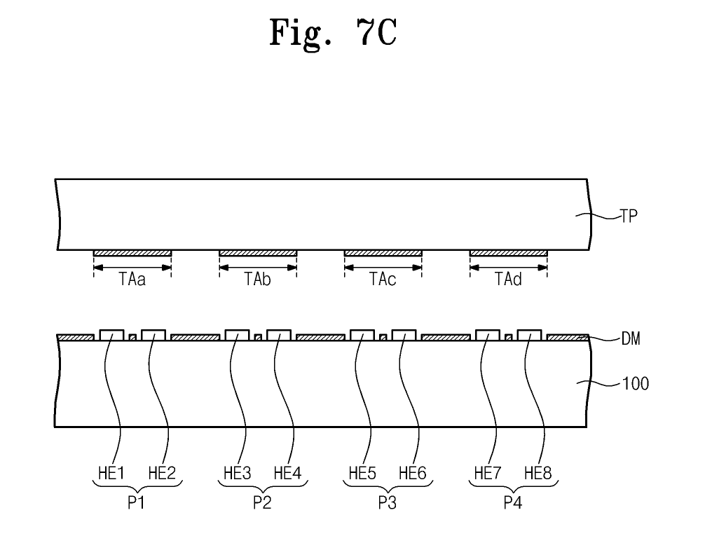

FIGS. 7a to 7c are cross-sectional views of another exemplary embodiment of a joule-heating evaporation deposition process according to the invention. Referring to FIGS. 7a to 7c, the joule-heating evaporation deposition method includes forming the deposition material, disposing the target substrate, and heating the heating electrodes, respectively.

FIG. 7a is a cross-sectional view of an exemplary embodiment of forming deposition material in a joule-heating evaporation deposition method according to the invention. Referring to FIG. 7a, the deposition material DM is formed (e.g., provided) on the base substrate 100 and the heating electrodes HE1 to HE8 to cover the base substrate 100 and the heating electrodes HE1 to HE8. The heating electrodes HE1 to HE8 are divided into four electrode pairs or groups. In detail, first and second heating electrodes HE1 and HE2 form the first electrode pair P1, the third and fourth heating electrodes HE3 and HE4 form the second electrode pair P2, the fifth and sixth heating electrodes HE5 and HE6 form the third electrode pair P3, and the seventh and eighth heating electrodes HE7 and HE8 form the fourth electrode pair P4.

FIG. 7b is a cross-sectional view of an exemplary embodiment of disposing the target substrate in the joule-heating evaporation deposition method according to the invention. Referring to FIG. 7b, the target substrate TP is disposed to face the base substrate 100. The first electrode pair P1 is disposed to face the first target area TAa, the second electrode pair P2 is disposed to face the second target area TAb, the third electrode pair P3 is disposed to face the third target area TAc, and the fourth electrode pair P4 is disposed to face the fourth target area TAd.

FIG. 7c is a cross-sectional view of an exemplary embodiment of heating the heating electrodes in the joule-heating evaporation deposition method according to the invention. Referring to FIG. 7c, the first to eighth heating electrodes HE1 to HE8 are heated by the power supply 300 to heat the deposition material DM disposed on, adjacent to and/or between the first to eighth heating electrodes HE1 to HE8. The deposition material DM is evaporated by the heat from the first to eighth heating electrodes HE1 to HE8 and provided to the target areas TAa to TAd of the target substrate TP, which respectively correspond to the first to fourth electrode pairs P1 to P4, thereby providing the layer on the target substrate TP formed of the deposition material DM. A portion of the original deposition material DM not sufficiently heated by the first to eighth heating electrodes HE1 to HE8, may remain on the base substrate 100, as illustrated in FIG. 7c, but the invention is not limited thereto or thereby.

Although exemplary embodiments of the invention have been described, it is understood that the invention should not be limited to these exemplary embodiments but various changes and modifications can be made by one ordinary skilled in the art within the spirit and scope of the invention as hereinafter claimed.

What is claimed is:

1. A heating evaporation deposition apparatus which deposits a layer on a target substrate, comprising:
a base substrate facing the target substrate comprising a plurality of target areas defined thereon;
a plurality of heating electrodes on the base substrate; and
a deposition material on the plurality of heating electrodes and an entire surface of the base substrate;
wherein plural heating electrodes among the plurality of heating electrodes respectively face each target area among the plurality of target areas.

2. The heating evaporation deposition apparatus of claim 1, wherein the plural electrodes comprises a pair of two heating electrodes among the plurality of heating electrodes.

3. The heating evaporation deposition apparatus of claim 1, wherein a distance between adjacent heating electrodes among the plural heating electrodes is to about 20% to about 40% of an overall width of the each target area.

4. The heating evaporation deposition apparatus of claim 1, wherein a width of each heating electrode among the plural heating electrodes respectively facing the each target area is about 30% to about 40% of an overall width of the each target area.

5. The heating evaporation deposition apparatus of claim 4, wherein a distance between adjacent heating electrodes among the plural heating electrodes is about 20% to about 40% of the overall width of the each target area.

6. The heating evaporation deposition apparatus of claim 1, wherein a distance between adjacent heating electrodes among the plural heating electrodes is in a range from about 2 micrometers to about 4 micrometers.

7. The heating evaporation deposition apparatus of claim 1, wherein a width of each heating electrode among the plural heating electrodes respectively facing the each target area is in a range from about 3 micrometers to about 5 micrometers.

8. The heating evaporation deposition apparatus of claim 7, wherein a distance between adjacent heating electrodes among the plural heating electrodes is in a range from about 2 micrometers to about 4 micrometers.

9. The heating evaporation deposition apparatus of claim 1, wherein a distance between the base substrate and the target substrate is in a range from about 2 micrometers to about 4 micrometers.

10. The heating evaporation deposition apparatus of claim 1, further comprising first and second common electrodes at opposing sides of the base substrate, respectively,
wherein the plurality of heating electrodes is between the first and second common electrodes, and electrically connected to the first and second common electrodes.

11. The heating evaporation deposition apparatus of claim 1, wherein
the each target area among the plurality of target areas has a rectangular planar shape elongated in a direction, and
each heating electrode among the plural heating electrodes respectively facing the each target area has an elongated bar shape corresponding to the rectangular planar shape of the each target area and extended in the direction.

12. The heating evaporation deposition apparatus of claim 1, wherein the target substrate is a display panel of a display device, and a target area among the plurality of target areas is a pixel area in which a pixel of the display panel is disposed.

13. The heating evaporation deposition apparatus of claim 12, wherein the deposition material comprises an organic light emitting material.

14. The heating evaporation deposition apparatus of claim 1, further comprising a power supply which is connected to the plurality of heating electrodes and heats the plurality of heating electrodes,
wherein the power supply applies a pulse voltage to the plurality of heating electrodes to heat the plurality of heating electrodes.

15. The heating evaporation deposition apparatus of claim 14, wherein the power supply individually applies the pulse voltage to respective heating electrodes among the plurality of heating electrodes to heat the plurality of heating electrodes.

16. A heating evaporation deposition method which deposits a layer on a target substrate, comprising:
providing a deposition material on an entire surface of a base substrate comprising a plurality of heating electrodes thereon;
defining a plurality of target areas on the target substrate;
disposing plural heating electrodes among the plurality of heating electrodes to face a corresponding target area among the plurality of target areas; and
heating the plural heating electrodes such that the deposition material on each heating electrode among the plural heating electrodes, is deposited in the corresponding target area.

17. The method of claim 16, wherein the plurality of heating electrodes is substantially simultaneously heated.

18. The method of claim 16, wherein the heating the one or more heating electrode comprises applying a pulse voltage to the one or more heating electrode to heat the one or more heating electrode.
